(19) United States
(12) Patent Application Publication
(10) Pub. No.: US 2014/0140881 A1
(43) Pub. Date: May 22, 2014

(54) METHOD FOR PRODUCING A THERMOELECTRIC SOLID ELEMENT

(71) Applicants: Bo Brummerstedt Iversen, Skodstrup (DK); Mogens Christensen, Aarhus N (DK); Hao Yin, Aarhus V (DK)

(72) Inventors: Bo Brummerstedt Iversen, Skodstrup (DK); Mogens Christensen, Aarhus N (DK); Hao Yin, Aarhus V (DK)

(73) Assignee: AARHUS UNIVERSITET, Aarhus C (DK)

(21) Appl. No.: 14/131,530

(22) PCT Filed: Jul. 16, 2012
(86) PCT No.: PCT/DK2012/050268

§ 371 Date: Jan. 8, 2014

(30) Foreign Application Priority Data
Jul. 15, 2011 (DK) PA 2011 70394

(51) Int. Cl. H01L 35/34; B22F 3/12

(52) U.S. Cl. CPC H01L 35/34; B22F 3/12
USPC 419/32

(57) ABSTRACT

The present invention relates to a method 931 for producing a solid element, which comprises the thermoelectrically active material beta-Zn4Sb3. The method utilizes that is possible to directly synthesize and press pellets of Zn4Sb3 starting from powders of Zn and Sb, by mixing 930 powders of Zn and Sb so as to obtain a mixed powder comprising elemental zinc and elemental antimony, placing 932 the mixed powder in a container and simultaneously applying 936 a pulsed current, such as to heat up the powders, and applying 938 a pressure such as to compact the powder mix. The gist of the invention might be seen as exploiting the basic insight, that the cumbersome and time- and energy consuming steps of synthesis and pressing of Zn and Sb, so as to achieve a solid element comprising Zn4Sb3, can be combined into a single step where the synthesis and pressing is effected simultaneously.

### FIELD OF THE INVENTION

The present invention relates to a method for producing a solid element comprising Zn₄Sb₃, more particularly the invention relates to a method for producing a solid element, a solid element, and a thermoelectric device comprising the solid element, where the solid element is produced in a short time and comprises beta-Zn₄Sb₃.

### BACKGROUND OF THE INVENTION

Increasing pressure on the environment and the energy supply has revived interest in the search for more efficient thermoelectric materials. The β-phase of Zn₄Sb₃ has been found to be an excellent p-type thermoelectric semiconductor when used in the intermediate temperature range (473-673 Kelvin). Good thermoelectric materials are typically heavily doped semiconductors with complex structures and large unit cells, which favour the preservation of a high power factor (S²σ), while various phonon scattering processes lower the thermal conductivity. It is three disordered interstitial Zn sites which endow β-Zn₄Sb₃ an unusually low thermal conductivity and makes it a competitive thermoelectric candidate. β-Zn₄Sb₃ has received considerable interest also because it is among the cheapest thermoelectric materials known, and it is made of non-toxic elements. However, the instability of Zn₄Sb₃ in the working temperature range limits its practical use in thermoelectric applications. It has been found that Zn₄Sb₃ starts to degrade even below 500 Kelvin (K) in air by loss of Zn, and occurrence of ZnSb, Sb and Zn (or its oxidation compound ZnO) as degradation products.

The reference “Preparation and thermoelectric properties of semiconducting Zn4Sb3”, by Caillat, T et al., J. Phys. Chem. Solids., 1997, 58, 1119-1125, describes production of single phase, polycrystalline material of β-Zn₄Sb₃ synthesized by quenching a melted mixture of stoichiometric Zn and Sb. Due to the different coefficients of thermal expansion of the multi phases of Zn₄Sb₃ during cooling, large crack-free bulk materials are difficult to obtain. To meet the physical and mechanical requirements of the practical use, hot-pressing is a necessity.

There is an aspiration in the art to arrive at a method for producing thermoelectric elements, such as Zn₄Sb₃ which would be commercially more advantageous than the known methods, such as more advantageous for large scale production.

Hence, an improved method for producing thermoelectric elements, such as a method which is commercially more advantageous, and in particular a more efficient, cheaper, more energy efficient, faster method, and/or a method which yields a solid element comprising Zn4Sb3 of higher quality, such as purer and/or more dense, would be advantageous.

### SUMMARY OF THE INVENTION

It is a further object of the present invention to provide an alternative to the prior art.

In particular, it may be seen as an object of the present invention to provide a method for producing a solid element comprising Zn₄Sb₃, a solid element comprising Zn₄Sb₃, and a thermoelectric device, that solves one or more of the above mentioned problems of the prior art by being commercially more advantageous, more efficient, cheaper, more energy efficient, faster and/or a method which yields a solid element of higher quality, such as purer and/or more dense.

Thus, the above described object and several other objects are intended to be obtained in a first aspect of the invention by providing a method for producing a solid element, such as pellet, comprising Zn₄Sb₃, the method comprising
mixing powders of elemental zinc and elemental antimony so as to obtain a mixed powder comprising elemental zinc and elemental antimony, such as comprising at least 50 wt % elemental zinc and/or elemental antimony,
placing the mixed powder in a container, such as a die, and
performing a combined synthesis and sintering process comprising
applying a pulsed current through the mixed powder, so as to increase the temperature of the mixed powder to an interval within 200-1000 degree Celsius, and
applying a pressure of at least 1 Mega Pascal to the mixed powder, and
   wherein the steps of applying the pulsed current through the mixed powder and applying the pressure to the mixed powder occur simultaneously.

The invention is particularly, but not exclusively, advantageous for obtaining an improved method for producing a solid element comprising Zn₄Sb₃, such as a method which is commercially more advantageous, and in particular a more efficient, cheaper, more energy efficient, faster method, and/or a method which yields a solid element of higher quality, such as purer and/or more dense.

It may be seen as a particular advantage, that embodiments according to the invention enables the fast production of a solid element comprising Zn4Sb3, such as the period of time from having the powders of elemental Zn and elemental Sb until a solid element of Zn4Sb3 is provided is within less than 24 hours, such as within 12 hours, such as within 8 hours, such as within 4 hours, such as within 2 hours, such as within 90 minutes, such as within 60 minutes, such as within 45 minutes, such as within 30 minutes, such as within 25 minutes, such as within 20 minutes, such as within 15 minutes, such as within 10 minutes, such as within 5 minutes. It may be added as another advantage, that in particular embodiments, there is not only provided the material Zn₄Sb₃, but it is also provided as a solid element, such as a high quality solid element, such as a phase pure beta-Zn₄Sb₃ solid element, such as a solid element comprising Zn₄Sb₃ which does not suffer from mechanical degradation (such as cracks appearing in the solid element) during cooling as has been the case with prior art methods.

The total process of synthesis and pressing, according to prior art methods, takes 4-8 hours, or more, excluding weighing chemicals, pumping vacuum and sealing quartz ampoules, grinding pre-synthesized rods and sieving powders. The typical relative density of the hot-pressed pellets, according to prior art methods, is 90-94%. Furthermore, long-time pressing (such as for a period of at least 15 minutes, 30 minutes, 60 minutes, 2 hours, 4 hours, 8 hours, 12 hours or 24 hours) at an elevated temperature (>673 Kelvin) will lead to substantial decomposition of Zn₄Sb₃. One of the present inventors has found that the thermoelectric zT value degraded to ⅓ after heating a quench synthesized sample to 673 K. This is described in the published patent application WO2006/128467A1 which is hereby incorporated by reference. It has also been suggested that adding extra Zn in synthesis to compensate lost Zn is an effective way to improve thermoelectric and mechanical properties.

In a particular embodiment, the method includes Spark Plasma Sintering (SPS). SPS technique is a pressing method which uses joule heat generated by the large currents passing through powders themselves and, possibly also a container, such as a graphite die, as the heat source. SPS can be used for obtaining mechanically stable and highly dense (˜100% density) pellets of Zn₄Sb₃. Owing to the fast heating rate, such as hundreds of degree per minute, the duration of the pressing process is reduced remarkably by SPS relative to conventional hot pressing. In the present application, we present a one-step process, where steps of respectively synthesizing and pressing Zn₄Sb₃ are combined and SPS is applied. More specifically, the step of synthesizing Zn₄Sb₃ from the elemental powders of Zn and Sb occurs simultaneously with the step of pressing the mixed powder into a pellet. The effects of the crucial parameters of SPS have been investigated.

In other words, SPS applies a high, pulsed current through the mixed powder, plasma is said to be generated between particles which helps reacting and compacting of the powder. SPS is described in “Sintering, consolidation, reaction and crystal growth by the spark plasma system (SPS)”, Omori, Materials Science and Engineering A, 2000, which is hereby incorporated by reference in entirety.

In this application, a one-step direct synthesis and pressing process for producing Zn₄Sb₃ using SPS is presented, i.e., the synthesis of Zn₄Sb₃ from powders of Zn and Sb is carried out simultaneously with the pressing of the mixed powder and/or the synthesized Zn₄Sb₃ powder, and is referred to as a one-step process since synthesis and pressing are carried out simultaneously. Dense pellets are obtained (relative density>99%) consisting of single phase beta-Zn₄Sb₃. Since the duration of maintaining the mixed powder at elevated temperatures is reduced remarkably, the decomposition of Zn₄Sb₃ is much limited. In specific embodiments, the whole process takes less than 0.5 hour. By adding an extra Zn foil to compensate Zn lost during sintering, a pure and homogeneous β-Zn₄Sb₃ pellet is produced. Compared to the traditional (sequential) synthesis (such as via quenching) and pressing, the direct synthesis and pressing method presented in the present application is faster, cheaper and purer. This might be preferable in the case of large scale production of Zn₄Sb₃, such as commercial production.

The gist of the invention might be seen as exploiting the basic insight, that the cumbersome and time- and energy consuming steps of synthesis and pressing of Zn and Sb, so as to achieve a solid element comprising Zn₄Sb₃, can be combined into a single step where the synthesis and pressing is effected simultaneously.

By a ‘powder’ is understood any solid substance reduced to a state of fine, loose particles, such as reduced by crushing, grinding, disintegration, milling, such as ball milling, such as hand milling, or the like. In particular embodiments, the powder may be sieved so as to have a diameter of 200 micron or below, such as 150 micron or below, such as 100 micron or below, such as 50 micron or below. A micron is understood to be a micrometer.

By a ‘solid element’ is understood a coherent, solid element, such as a pellet. In specific embodiments, the solid element may have a particular size, such as having a volume within 1 mm³ (cubic millimetres) to 1e-3 m³ (cubic metres), such as within 10 mm³ (cubic millimetres) to 1e-4 m³ (cubic metres). In specific embodiments, the solid element may have a particular shape, such as having at least one substantially planar surface, such a planar surface, such as having a disk like shape, such as having at least one dimension which is substantially smaller than the other two dimensions, such as having a dimension which is less than half the length of the other two dimensions. In particular embodiments, the solid element is understood to be mechanically stable, such as measured by a method capable of quantifying hardness.

The lateral dimensions of the solid element, such as the dimensions in a plane, such as the diameter, may range from 4 mm up to 18 mm diameter. In one embodiment, the thickness of the solid element, such as the dimension in a direction orthogonal to said plane, is within a range of 0.1 mm to 50 mm, such as 0.1 mm to 30 mm, such as 0.1 mm to 20 mm, such as 0.1 mm to 15 mm, 0.1 mm to 10 mm, such as 0.1 mm, such as 0.5 mm, such as 1 mm, such as 1.5 mm, such as 2 mm, such as 5 mm, such as 10 mm, such as within a range of 1 mm to 5 mm. Other diameters, however, are also conceivable. It is also possible to cut the solid element into many smaller solid elements, such as 1 mm×1 mm, such as 1 mm×1 mm×1 mm. Providing a plurality of appropriately sized solid elements may be advantageous for implementation in a thermoelectric device.

By a ‘pulsed current’ is understood a current with a magnitude which varies over time, such as a current which has peak values which are higher than values in between pulses, such as at least 2 times higher, such as at least 5 times higher, such as at least 10 times higher, such as at least 100 times higher, such as at least 1000 times higher, such as the current between pulses being substantially zero, such as zero. A ‘pulsed current’ may be understood to have a plurality of pulses, such as increases and decreases in the current over time, such as at least 5 pulses per second, such as at least 10 pulses per second, such as at least 20 pulses per second, such as at least 50 pulses per second, such as at least 100 pulses pers second. The pulses may have a width, such as described by the full width at half maximum (FWHM), wherein the width is within 0.01 ms-1 s, such as within 0.01 ms-0.5 s, such as within 0.1 ms-0.5 s, such as within 0.5 ms-0.5 s, such as within 1 ms-0.5 s, such as within 1 ms-0.1 s, such as within 1 ms-50 ms, such as within 1-10 ms, such as within 1-5 ms, such as within 2-4 ms. The peak values of the current may be above 1 A, such as above 5 A, such as above 10 A, such as above 50 A, such as above 100 A, such as above 150 A, such as above 200 A, such as above 250 A, such as above 300 A, such as above 500 A, such as above 1000 A. In a particular embodiment the period of the pulses is 3.3 milliseconds. In a particular embodiment, the pulsed current is applied in cycles, in which each cycle comprises a number of pulses, such as 12 (corresponding to e.g., 39.6 milliseconds), followed by a number of periods of no current, such as 2 (corresponding to, e.g., 6.6 ms). The peak values of the pulses may in a particular embodiment be, e.g., 200 Ampere or 300 Ampere.

Current is understood to be electrical current, i.e., a flow of electrical charge. By a ‘container’ is understood anything that contains or can contain a powder or a solid element, and it is understood to comprise any entity which can hold an amount of powder, while the powder is exposed to pressure. In a particular embodiment, the container may be embodied by a die.

By a ‘die’ is understood a device for holding a material, such as the material being a powder or a solid element, during a pressing. The die may be a hollow device of, e.g., steel or graphite.

By ‘simultaneously’ is understood that a plurality of events takes place simultaneously, i.e., within the same period of time, such as the time-period where the first event takes place overlaps with the time-period where the second event takes place. In a particular embodiment, the first event is applying a pulsed current and the second event is applying a pressure, and it is understood that if the period in which a pulsed current is applied overlaps with the period in which the pressure is applied, then the steps of applying a pulsed current and the step of applying a pressure overlaps and can be said to occur simultaneously.

By ‘sintering’ is understood the process of bringing about an agglomeration by heating, such as a process in which metal particles can be joined together by melting only a surface layer of the metal particles, which metal particles are placed adjacent each other and in physical contact.

By ‘synthesis’ is understood a process in which a new compound (such as beta-Zn₄Sb₃) is provided by exposing one or more other compounds (such as Zn and Sb) to certain conditions, such as an applied pulsed current and pressure, which may be applied simultaneously.

It should be noted that in the present application and in the appended claims, the term “a material having the stoichiometric formula Zn₄Sb₃” is to be interpreted as a material having a stoichiometry which traditionally and conventionally has been termed Zn₄Sb₃ and having a Zn₄Sb₃ crystal structure. However, it has recently been found that these materials having the Zn₄Sb₃ crystal structure contain interstitial zinc atoms making the exact stoichiometry Zn_{12.82}Sb₁₀, equivalent to the stoichiometry Zn_{3.846}Sb₃ (cf. Disordered zinc in Zn₄Sb₃ with Phonon Glas, Electron Crystal Thermoelectric Properties, Snyder, G. J.; Christensen, M.; Nishibori, E.; Rabiller, P.; Caillat, T.; Iversen, B. B., Nature Materials 2004, 3, 458-463; and Interstitial Zn atoms do the trick in Thermoelectric Zinc Antimonide, Zn₄Sb₃. A combined Maximum Entropy Method X-Ray Electron Density and an Ab Initio Electronic Structure Study, Caglioni, F.; Nishibori, 20 E.; Rabiller, P.; Bertini, L.; Christensen, M.; Snyder, G. J.; Gatti, C.; Iversen, B. B., Chem. Eur. J. 2004, 10, 3861-3870). In the present application and in the appended claims the optional substitution of one or more elements selected from the group comprising Sn, Mg, Pb and the transition metals in a total amount of 20 mol % or less in relation to the Zn atoms is based on the amount of Zn atoms of the exact stoichiometry Zn₄Sb₃. Accordingly, the stoichiometry of a material having the maximum degree of substitution of metal X is Zn_{3.2X0.8}Sb₃.

According to another embodiment of the invention, there is provided a method for producing a solid element, such as pellet, comprising Zn₄Sb₃, wherein no sintering of the mixed powder is performed prior to the combined synthesis and sintering process.

According to another embodiment of the invention, there is provided a method for producing a solid element, such as pellet, comprising Zn₄Sb₃, the method consisting of
mixing powders of elemental zinc and elemental antimony so as to obtain a mixed powder comprising elemental zinc and elemental antimony, such as comprising at least 50 wt % elemental zinc and/or elemental antimony,
placing the mixed powder in a container, such as a die, and
performing a combined synthesis and sintering process comprising
   applying a pulsed current through the mixed powder, so as to increase the temperature of the mixed powder to an interval within 200-1000 degree Celsius, and
   applying a pressure of at least 1 Mega Pascal to the mixed powder, and
      wherein the steps of applying the pulsed current through the mixed powder and applying the pressure to the mixed powder occur simultaneously.

According to another embodiment of the invention, there is provided a method, wherein the produced solid element is phase pure, such as at least 90.0 wt % being Zn₄Sb₃, such as at least 95 wt % being Zn₄Sb₃, such as at least 98 wt % being Zn₄Sb₃, such as at least 99 wt % being Zn₄Sb₃, such as at least 99.5 wt % being Zn₄Sb₃, such as at least 99.9% being Zn₄Sb₃. By ‘phase purity’ is understood that substantially only a single phase is present in the solid element, such as a single phase. A possible advantage of having a phase pure material is that the thermoelectrical properties of the solid element, such as the ability to maintain a high zT value over time, or when exposed to high temperatures or thermal cycling.

In a particular embodiment of the present invention, the Zn₄Sb₃ phase is β-Zn₄Sb₃ (beta-Zn₄Sb₃).

According to another embodiment of the invention, there is provided a method, wherein the produced solid element has a relative density of at least 90%, such as at least 95%, such as at least 98%, such as at least 99%, such as at least 99.5%, such as at least 99.9%, as measured with respect to 6.39 g/cm̂3, i.e., by relative density of 100% is understood a density of 6.39 g/cm̂3. An advantage of having a higher relative density might be that thermoelectric and mechanical properties are prone to deterioration when the solid element is less dense. The article “Influence of sample compaction on the thermoelectric performance of Zn4Sb3”, by Pedersen, B. L., et al., Appl. Phys. Lett., 89, 2006, which is hereby incorporated by reference in entirety, is a study on Zn4Sb3 which shows that a change in density from 91% to 99% changes zT by a factor of three at 400 K.

According to another embodiment of the invention, there is provided a method, wherein the produced solid element is mechanically stable. The increased mechanical stability of the solid element may ensure that samples can withstand simple handling, such as moving and general handling by hand. In an embodiment of the invention, the hardness (Hv) of the solid element is within 0.1-10 GPa, such as within 0.5-5 GPa, such as within 1-4 GPa, such as within 1.5-3 GPa, such as at least 0.5 GPa, such as at least 1 GPa, such as at least 1.5 GPa, such as at least 2 GPa, such as at least 2.5 GPa, such as at least 3 GPa. According to another embodiment of the invention, there is provided a method, wherein the method further includes the step of placing an element comprising zinc adjacent to the mixed powder, such as in physical contact with the mixed powder, such as in electrical contact with the mixed powder, such as to allow zinc ions to electromigrate from the element to the mixed powder during the step of applying the pulsed current through the mixed powder. By having an element comprising zinc adjacent to the mixed powder, negative effects of electromigration of Zn (which may be present since Zn might migrate within the mixed powder under influence of the applied current) may be substantially overcome, such as overcome, since Zn may emanate from the element comprising zinc adjacent to the mixed powder, and refill Zn depleted regions in the mixed powder.

According to one other embodiment of the invention, wherein the element comprising Zn is foil. By foil is understood a coherent layer, which in one dimension is small compared to the other two dimensions. The foil may be flexible. An advantage of using a foil may be that a relatively thin layer of material may be placed in the correct position during manufacture in a fast and uncomplicated manner during preparation. Another possible advantage may be that when using a foil, the element comprising Zn may obtain a well defined material composition, purity and thickness. In another possible embodiment the second layer is a solid, rigid element, such as having a size similar to the solid element in at least 2 dimensions. In another possible element, the element comprising zinc is embodied as a powder which is compressed during preparation. In another possible embodiment, the element comprising zinc is embodied as a powder which is compressed during preparation.

According to another embodiment of the invention, there is provided a method, wherein the pressure which is applied to the mixed powder is at least 60 Mega Pascal, such as above 60 Mega Pascal, such as at least 65 Mega Pascal, such as at least 70 Mega Pascal, such as at least 80 Mega Pascal, such as at least 85 Mega Pascal, such as at least 90 Mega Pascal, such as at least 95 Mega Pascal, such as at least 100 Mega Pascal, such as 100 Mega Pascal. A possible advantage of having the pressure which is applied to the mixed powder being at least this pressure, may be that it enables less decomposition of the Zn₄Sb₃ material during synthesis and pressing. This may be described as surprising, i.e., that a solid element produced a relatively high pressure, such as 100 MPa, may decompose very little, as compared to solid elements pressed with lower pressure (60 MPa and 30 MPa). One could expect that due to the closer contact among the grains, Zn diffusion should be take place to a larger extent, which could be assumed to lead to more decomposition. However, higher contact resistance between the grains at lower pressure, may lead to elevated currents during heating.

In a particular embodiment, the pressure applied is within the range of 1-300 Mega Pascal, e.g. 150 Mega Pascal, such as within the range of 2-250 Mega Pascal, e.g. 140 Mega Pascal, such as within the range of 5-225 Mega Pascal, e.g. 130 Mega Pascal, such as within the range of 10-200 Mega Pascal, e.g. 120 Mega Pascal, such as within the range of 20-175 Mega Pascal, e.g. 120 Mega Pascal, such as within the range of 30-150 Mega Pascal, e.g. 110 Mega Pascal, such as within the range of 40-125 Mega Pascal, e.g. 100 Mega Pascal, such as within the range of 50-100 Mega Pascal, e.g. 90 Mega Pascal, such as within the range of 60-100 Mega Pascal, e.g. 80 Mega Pascal, such as within the range of 70-90 Mega Pascal, e.g. 75 Mega Pascal, such as within the range of 90-110 Mega Pascal, e.g. 95 Mega Pascal, such as within the range of 95-105 Mega Pascal.

In a particular embodiment, the pressing is uniaxial pressing, such as the pressure which is applied is applied in one direction. This may be advantageous in order to achieve a uniform densification and the production of a compact solid element.

According to another embodiment of the invention, there is provided a method, wherein the applied current through the mixed powder is large enough to heat the sample to at least 350 degree Celsius, such as within the range of 200-950 degree Celsius, e.g. 355 degree Celsius, such as within the range of 210-900 degree Celsius, e.g. 365 degree Celsius, such as within the range of 220-850 degree Celsius, e.g. 375 degree Celsius, such as within the range of 250-800 degree Celsius, e.g. 385 degree Celsius, such as within the range of 275-750 degree Celsius, e.g. 395 degree Celsius, such as within the range of 300-700 degree Celsius, e.g. 405 degree Celsius, such as within the range of 310-650 degree Celsius, e.g. 415 degree Celsius, such as within the range of 320-600 degree Celsius, e.g. 425 degree Celsius, such as within the range of 330-550 degree Celsius, e.g. 435 degree Celsius, such as within the range of 350-500 degree Celsius, e.g. 425 degree Celsius, such as within the range of 375-450 degree Celsius, e.g. 405 degree Celsius, such as within the range of 390-410 degree Celsius. An advantage of applying a current through the mixed powder which is large enough to heat the sample to a temperature within such interval may be that less decomposition, such as decomposition of Zn₄Sb₃ to ZnSb, of the solid element is observed for higher temperatures. In another embodiment the applied current through the mixed powder is large enough to heat the sample to at least 345 degree Celsius, such as at least 355 degree Celsius, such as at least 360 degree Celsius, such as at least 365 degree Celsius, such as at least 370 degree Celsius, such as at least 375 degree Celsius, such as at least 380 degree Celsius, such as at least 385 degree Celsius, such as at least 395 degree Celsius, such as at least 390 degree Celsius, such as at least 395 degree Celsius, such as at least such as at least 400 degree Celsius, such as to 400 degree Celsius. An advantage of applying a current through the mixed powder which is large enough to heat the sample to at least this temperature may be that less decomposition, such as decomposition of Zn₄Sb₃ to ZnSb, of the solid element is observed for higher temperatures.

According to another embodiment of the invention, there is provided a method, wherein the applied current through the mixed powder is adapted so as to heat the sample to at most 550 degree Celsius, such as at most 545 degree Celsius, such as at most 540 degree Celsius, such as at most 535 degree Celsius, such as at most 530 degree Celsius, such as at most 525 degree Celsius, such as at most 520 degree Celsius, such as at most 515 degree Celsius, such as at most 510 degree Celsius, such as at most 505 degree Celsius, such as at most 500 degree Celsius, such as to 400 degree Celsius. An advantage of applying a current through the mixed powder which is adapted so as to heat the sample to at most this temperature may be that less decomposition, such as decomposition of Zn4Sb3 into another phase with lower Seebeck coefficient, of the solid element is observed for lower temperatures.

In a particular embodiment, there is provided a method wherein the mixed powder is heated to a temperature within 350 degree Celsius to 500 degree Celsius.

According to another embodiment of the invention, there is provided a method, wherein the applied current is substantially turned off, such as completely turned off, within less than 24 hours, such as within 12 hours, such as within 8 hours, such as within 4 hours, such as within 2 hours, such as within 90 minutes, such as within 60 minutes, such as within 45 minutes, such as within 30 minutes, such as within 25 minutes, such as within 20 minutes, such as within 15 minutes, such as within 10 minutes, such as within 5 minutes. One possible advantage of providing a method, wherein the applied current is substantially turned off within this amount of time may be that a reduction in time and/or energy consumption is achieved. One other possible advantage may be that a significant growth of the region of the solid element which is degraded from Zn4Sb3 to ZnSb can be seen with increasing time. One other possible advantage may be that homogeneity of the solid element can be seen to degrade with increasing time.

According to another embodiment of the invention, there is provided a method, wherein the applied pressure is released, such as reduced to atmospheric pressure, within less than 24 hours, such as within 12 hours, such as within 8 hours, such as within 4 hours, such as within 2 hours, such as within 90 minutes, such as within 60 minutes, such as within 45 minutes, such as within 30 minutes, such as within 25 minutes, such as within 20 minutes, such as within 15 minutes, such as within 10 minutes, such as within 5 minutes. One possible advantage of providing a method, wherein the applied current is substantially turned off within this amount of time, may be that a reduction in time and/or energy consumption is achieved. One other possible advantage may be that a significant growth of the region of the solid element which is degraded from Zn₄Sb₃ to ZnSb can be seen with increasing time. One other possible advantage may be that homogeneity of the solid element can be seen to degrade with increasing time.

According to another embodiment of the invention, there is provided a method, wherein the heating rate is at least 50 degree Celsius per minute, such at least 75 degree Celsius per minute, such as at least 100 degree Celsius per minute, such as at least 125 degree Celsius per minute, such as at least 150 degree Celsius per minute. One possible advantage of providing a method, wherein the heating rate is given by these values, may be that less decomposition, such as decomposition of Zn₄Sb₃ to ZnSb, of the solid element is observed for higher heating rates. The fast heating which may be provided by using resistive heating, such as using resistive heating with a pulsed current, enables high heating rates, such as 40 K/minute, so as to reach 400 degrees Celsius (from room temperature) within 10 min, or 125 K/minute such as to reach 400 degrees Celsius (from room temperature) within 3 min. In general, the longer time the mixed powder is heated, the more it degrades (such as changes phase from Zn₄Sb₃ to ZnSb).

According to another embodiment of the invention, there is provided a method, wherein the heating rate is at most 50 degree Celsius per minute, such as at most 75 degree Celsius per minute, such as at most 100 degree Celsius per minute, such as at most 125 degree Celsius per minute, such as at most 150 degree Celsius per minute. One possible advantage of providing a method, wherein the heating rate is given by these values, may be that more dense solid elements may be obtained for lower heating rates.

In a particular embodiment, the heating rate is within the range of 10-500 degree Celsius per minute, e.g., 200 degree Celsius per minute, such as within the range of 20-400 degree Celsius per minute, e.g. 210 degree Celsius per minute, such as within the range of 25-350 degree Celsius per minute, e.g. 200 degree Celsius per minute, such as within the range of 30-320 degree Celsius per minute, e.g. 300 degree Celsius per minute, such as within the range of 35-300 degree Celsius per minute, e.g. 250 degree Celsius per minute, such as within the range of 40-350 degree Celsius per minute, e.g. 100 degree Celsius per minute, such as within the range of 45-300 degree Celsius per minute, e.g. 155 degree Celsius per minute, such as within the range of 50-250 degree Celsius per minute, e.g. 225 degree Celsius per minute, such as within the range of 50-200 degree Celsius per minute, e.g. 135 degree Celsius per minute, such as within the range of 50-175 degree Celsius per minute, e.g. 145 degree Celsius per minute, such as within the range of 50-150 degree Celsius per minute, e.g. 115 degree Celsius per minute, such as within the range of 50-130 degree Celsius per minute.

According to another embodiment of the invention, there is provided a method, wherein the mixed powder has a composition corresponding to the stoichiometric formula Zn₄Sb₃, wherein part of the Zn atoms are optionally being substituted by one or more elements selected from the group comprising Sn, Mg, Pb and/or a transition metal in a total amount of 20 mol % or less in relation to the Zn atoms.

According to a second aspect of the invention, the invention further relates to a solid element, such as a pellet, comprising Zn₄Sb₃, which is produced according to the first aspect.

According to a third aspect of the invention, the invention further relates to a thermoelectric device comprising a solid element according to the second aspect.

By ‘thermoelectric device’ is understood a device which is capable of creating a voltage when there is a different temperature on each side of the device. In practical thermoelectric devices, typically at least two thermoelectric legs are inserted, which legs are of different types.

To get an operational thermoelectric device the solid element has to be contacted electrically. This may be done by contacting the Zn₄Sb₃ pellet with electrical connecting elements, such as Cu rods, such as Cu rods having a size so as to match the entire diameter of the solid element, such as a Zn₄Sb₃ pellet. In one particular embodiment, the one or more electrically connecting elements are placed adjacent to the solid element during the combined synthesis and sintering, such as the one or more electrically connecting elements are contacted to the solid element during the combined synthesis and sintering. A possible advantage of this may be that is saves the process step of electrically connecting the solid element with the one or more electrically connecting elements afterward the solid element has been produced. Another possible advantage might be that the soldering or brazing may be avoided. In a further embodiment, one or more Zn-foils is/are placed between the one or more electrically connecting elements and the solid element during synthesis and pressing. This Zn foil serves as a Zn reservoir, so that possibly lost Zn inside the solid element may be refilled during synthesis/pressing, such as during applying a current which may cause electromigration of Zn.

This aspect of the invention is particularly, but not exclusively, advantageous in that the method according to the present invention may be implemented by . . . .

The first, second and third aspect of the present invention may each be combined with any of the other aspects. These and other aspects of the invention will be apparent from and elucidated with reference to the embodiments described hereinafter.

### BRIEF DESCRIPTION OF THE FIGURES

The a method for producing a solid element, a solid element, and a thermoelectric device according to the invention will now be described in more detail with regard to the accompanying figures. The figures show one way of implementing the present invention and is not to be construed as being limiting to other possible embodiments falling within the scope of the attached claim set.

FIG. 1 shows a solid element which is mounted for Seebeck micro probe measurements,

FIG. 2 shows a Seebeck microprobe scanning pattern for a solid element,

FIG. 3 shows X-ray patterns corresponding to ZnSb and Zn4Sb3,

FIG. 4 shows Seebeck microprobe scans for samples produced using various sintering times,

FIG. 5 shows Seebeck microprobe scans for samples produced using various heating rates,

FIG. 6 shows Seebeck microprobe scans for samples produced using various sintering temperatures,

FIG. 7 shows Seebeck microprobe scans for samples produced using various applied pressures,

FIG. 8 shows Seebeck microprobe scans for samples produced with and without having an element comprising zinc placed next to the mixed powder,

FIG. 9 is a flow-chart of a method according to the invention,

FIG. 10 is an exemplary current vs. time curve,

FIGS. 11-16 show, respectively FIGS. 2, 4-8 with another color scale.

### DETAILED DESCRIPTION OF AN EMBODIMENT

According to a particular embodiment of the invention, the solid element (which may elsewhere in this application be referred to interchangeably as a ‘pellet’ or ‘sample’) may be produced as described in the following. Stoichiometric zinc (Zn) (powder, with a grain size diameter <45 micron (μm), pro analysis, MERCK KGaA) and antimony (Sb) (powder, grain size diameter <150 micron (μm), 99.5%, SIGMA-ALDRICH CHEMIE GmbH) are weighed with the Zn:Sb ratio of 4:3. The powders are mixed in a ball mill mixer (SpectroMill, CHEMPLEX INDUSTRIES, INC) for 15 minutes. 2.5 g of the mixed powder is loaded into a container, being a graphite die, with a diameter of 12.7 mm. The step of applying the pressure (which elsewhere in this application may be interchangeably referred to as ‘pressing’) is carried out on a DR. SINTER LAB (SPS-5155, SPS SYNTEX). The DC pulse generator is a peak number control system, which tunes the direct current “on time” within the range of 1˜99 digit (3.3 ms-326.7 ms at 50 Hz), “off time” in 1˜9 digit (3.3 ms-29.7 ms at 50 Hz). The default parameters, which have been applied in the present application, are 12 (on) and 2 (off). SPS applies high current through the powder, plasma is said to be generated between particles which helps reacting and compacting of the powder.

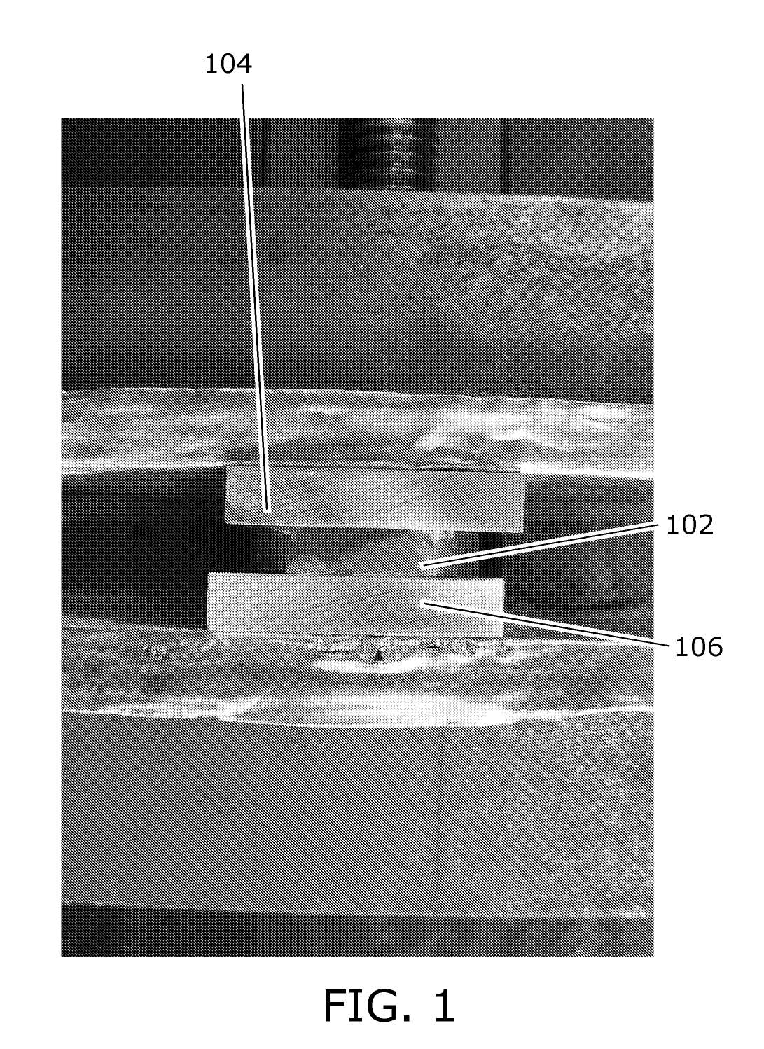

The density of the as pressed solid element, which in the present embodiment takes the shape of a disc, is measured using Archimedes technique. X-ray diffraction is used to analyse the phase purity of the pellets. The pellets are then cut perpendicular to the sides, i.e., the plane of cutting lies substantially parallel, such as parallel, to a direction through the pellets which was parallel with a direction of the current during Spark Plasma Sintering (SPS). The sections, i.e., the sides of the pellets which have been laid open via cutting, are polished before the Seebeck micro probe measurements are carried out. To make sure that the edges of the pellets are detected by the probe, two nickel (Ni) pieces are used to sandwich the pellet (see FIG. 1). Since nickel has very low Seebeck values, the areas corresponding to nickel will show up clearly in the Seebeck scans so as to delimit the region corresponding to the Zn4Sb3 pellet.

The effects of SPS parameters sintering time tₛ, applied current (tuned by heating rate, corresponding to heating ramp time tₕ), sintering temperature T, applied pressure P are investigated respectively. The influence of adding extra Zn layer is also studied.

FIG. 1 is a photograph showing a pellet 102 (where the side which can be seen—and measured upon—is the side which has been laid open by the cut, and thus corresponds to the interior of the pellet which was produced), a first layer of nickel 104 and a second layer of nickel 106.

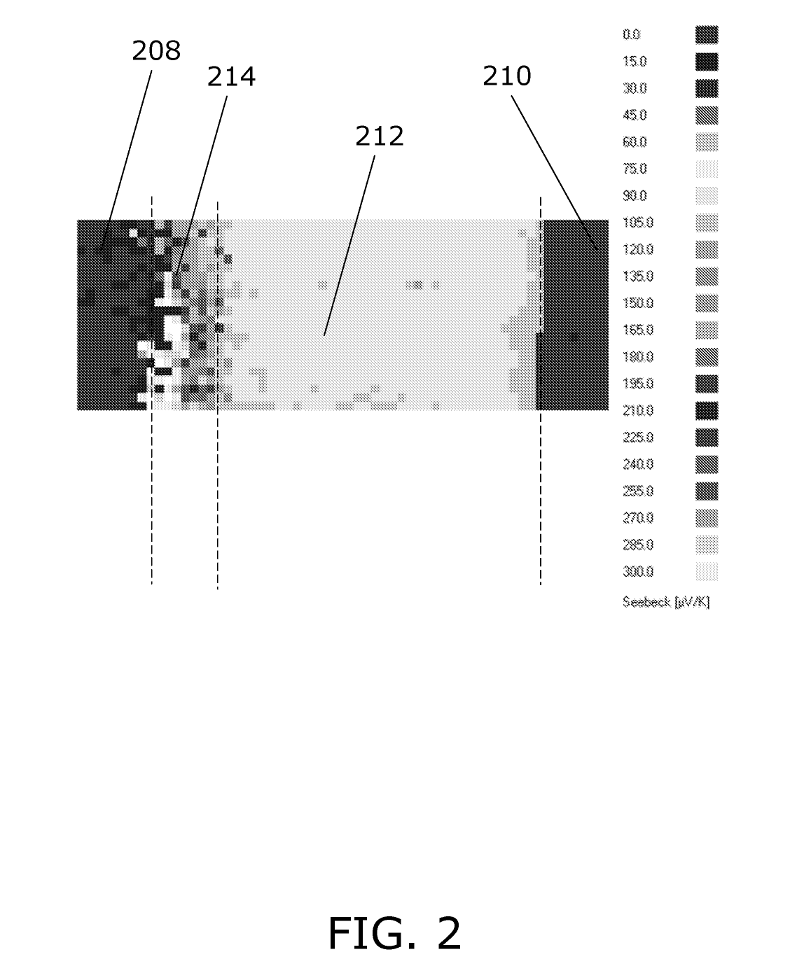

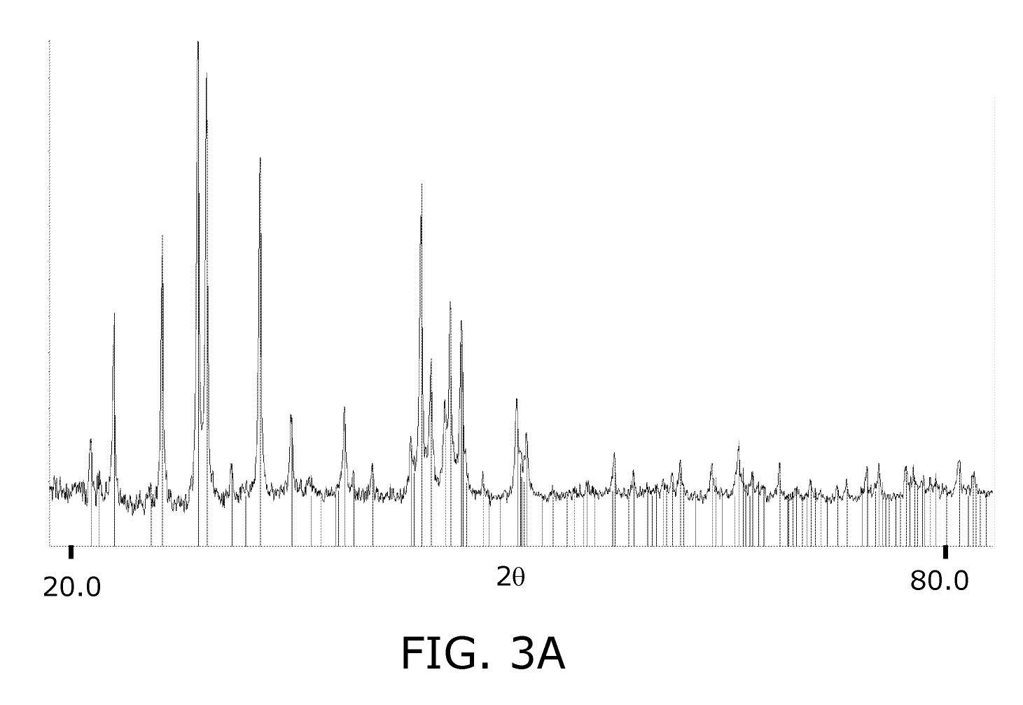

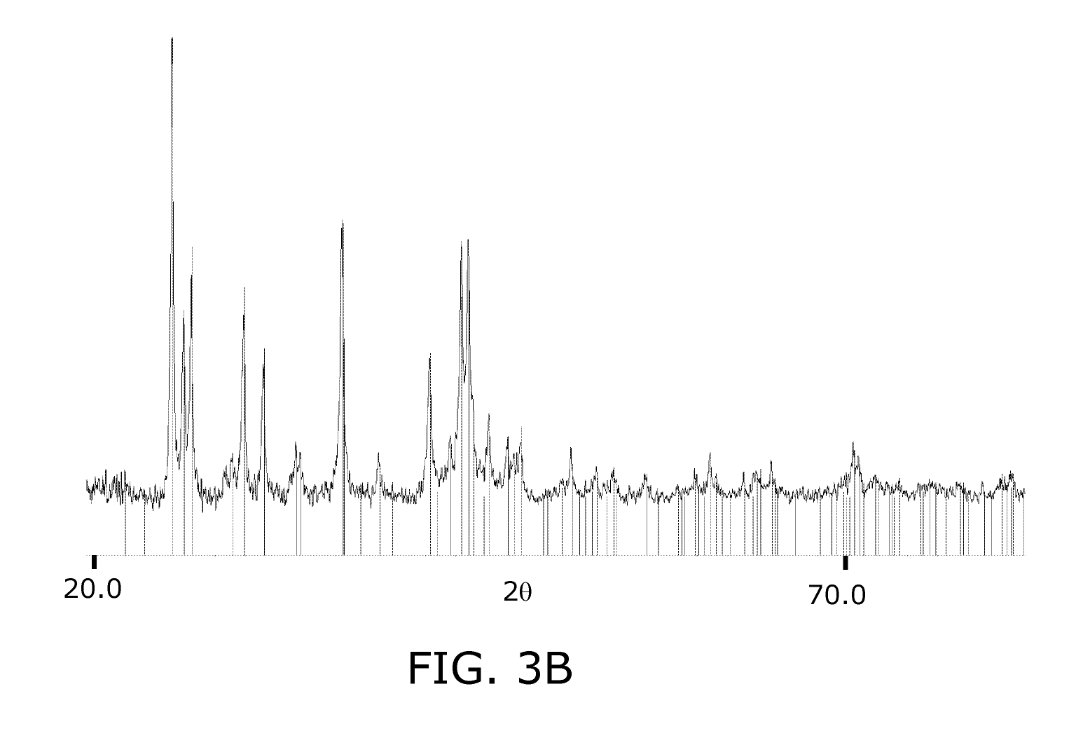

FIG. 2 shows a Seebeck micro probe scanning pattern for a solid element which is produced with the conditions heating ramp time 3 minute (such as heating rate corresponding to 125 K/minute), sintering temperature 400 degree Celcius, sintering time 15 minutes, pressure 100 MPa, without Zn foil (i.e., no zinc comprising element placed adjacent the mixed powder). Seebeck microprobe scanning is carried out at room temperature in ambient, atmospheric air. The resolution was set to 50 micrometers. The figure shows a scan of the side of the pellet, where the Seebeck coefficient which is measured in a given area is marked in the figure by the corresponding colour. It is noted that in each of FIGS. 2, 4-8, the colour scale in the right hand side spans 0-300 microV/K in steps of 15 microV/K. In FIG. 2, the dark areas 208, 210 on both sides correspond to Ni, which has near-zero Seebeck coefficient at room temperature. The direct current of SPS comes in from the left hand side and goes out to the right. Thus, the electrons in the current move through the material from right to left. The large area 212 corresponds to the Zn₄Sb₃ phase, which has a Seebeck coefficient in the range of 70-140 microvolt/Kelvin (microμV/K) at room temperature. The area 214 which exhibit Seebeck coefficients near 200 microV/K or even higher is ZnSb. X-ray diffraction patterns confirm this phase assignment (FIG. 3). It might be possible that the ZnSb phase is generated when the Zn₄Sb₃ phase loses some Zn. Zn ions are driven by the direct current and migrate in the same direction as the current.

FIG. 3 shows X-ray diffraction patterns which have been obtained from solid elements, such as the solid element which has been measured upon for obtaining the Seebeck microprobe scan of FIG. 2. The detection limit of the used X-ray diffractometer is approximately 2 wt %. The X-ray patterns are obtained via X-ray powder diffraction (XRPD), of powder of the pellet, where the powder is carefully filed off from one end of the pellet.

FIG. 3A shows an X-ray diffraction patterns which has been obtained from an area similar to the area 214 in FIG. 2. All peaks can be indexed to ZnSb, and it is hence confirmed, that the material responsible for the high Seebeck coefficients in the left area 214 of FIG. 2 is indeed ZnSb. FIG. 3A corresponds to the side where the current comes in.

FIG. 3B shows an X-ray diffraction patterns which has been obtained from an area similar to the area 212 in FIG. 2. All peaks can be indexed to Zn4Sb3, and it is hence confirmed, that the material responsible for the Seebeck coefficients in the range 70-140 microV/K in the right area 212 of FIG. 2 is indeed Zn4Sb3. FIG. 3B corresponds to the side where the current exits.

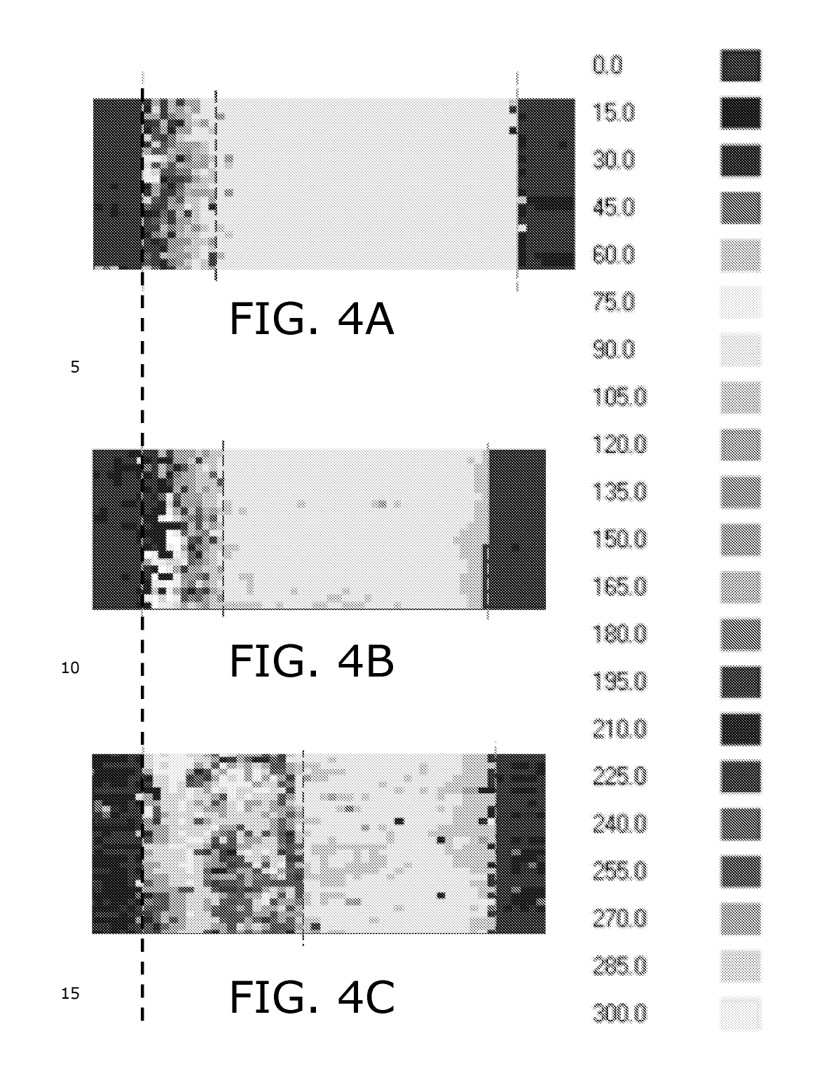

FIG. 4 shows a plot of the Seebeck micro probe scanning patterns of pellets with various sintering times

FIG. 4A corresponds to a sintering time of 10 minutes, FIG. 4B corresponds to a sintering time of 15 minutes and FIG. 4C corresponds to a sintering time of 20 minutes. The heating profile is kept unchanged, i.e. from room temperature to 400 degree Celsius within 3 minutes (tₕ=3 minutes). The pressure applied (P) is 100 Mega Pascal (MPa). The relative densities of the three samples are 99%, 99.9% and 99% compared with 6.39 g/cm³. As in all of FIGS. 2, 4-8, guides to the eye (dashed, vertical lines) are added to enable comparing the width of each phase with the width of the corresponding phase for pellets exposed to different conditions, such as different sintering times. The left side line is drawn where the first two pixels of the ZnSb portion of the pellet (as opposed to the nickel appear (corresponding to a value of a least 200 microV/K), and where the two spots are adjacent to each other; the middle one is similarly drawn where the first two successive pixels corresponding to the ZnSb portion disappear (corresponding to a value of a least 200 microV/K); the right side line is drawn where the last two successive pixels of the pellet (Zn₄Sb₃) disappear (corresponding to a value of a least 60 microV/K). A significant growth of the width of ZnSb phase can be seen with the increase of the sintering time. It can also be seen, that the homogeneity of the Zn₄Sb₃ increases with decreasing pressing time.

Since the heat of SPS pressing is provided internally by the current, the applied current through the material during heating can be tuned by the heating rate.

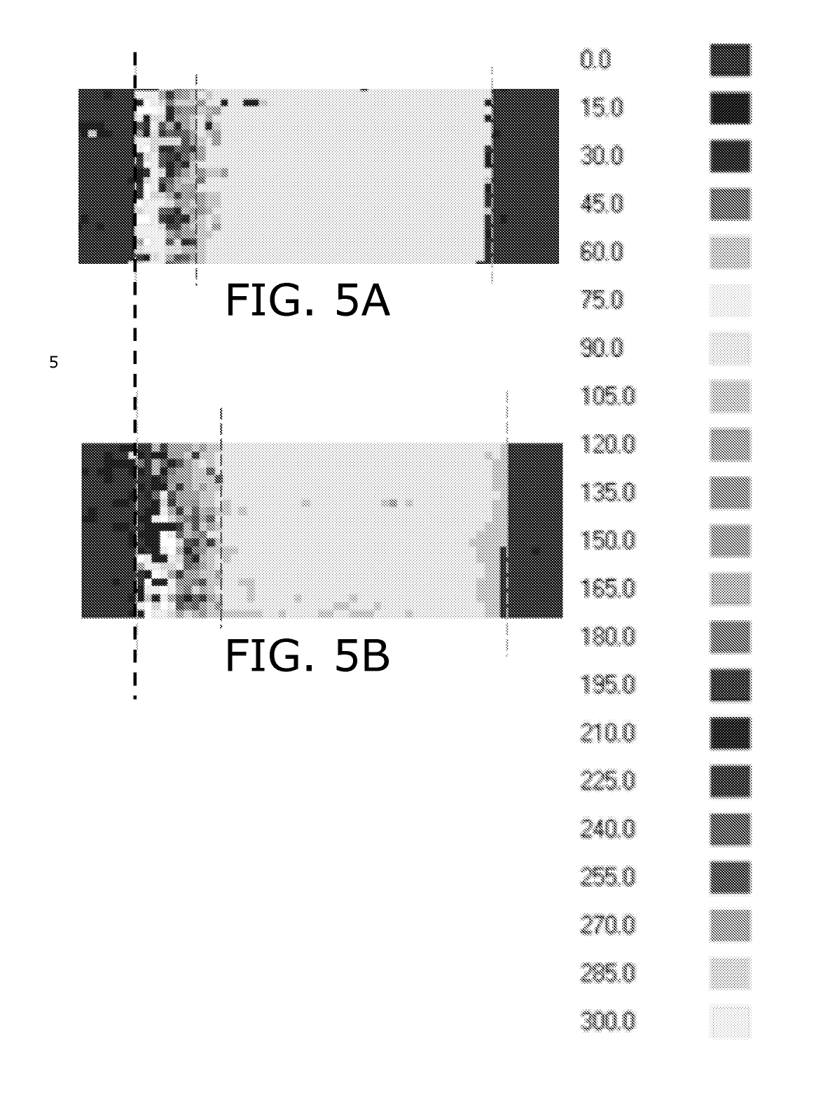

FIG. 5 shows the influence of applied current to the phase composition of the pellets. All the other parameters are kept unchanged (sintering time tₛ=15 minutes, sintering temperature T=400 degree Celsius and applied pressure P=100 MPa).

FIG. 5A corresponds to a pellet which has been produced with a heating rate corresponding to a heating ramp time tₕ=3 minutes, i.e., the temperature increases from room temperature (RT) to 400 degree Celsius in a period of 3 minutes.

FIG. 5B corresponds to a pellet which has been produced with a heating rate corresponding to a heating ramp time tₕ=5 minutes, i.e., the temperature was increased from room temperature to 400 degree Celsius in a period of 5 minutes.

The relative densities of the two pellets are 99.9% (FIG. 5A, tₕ=3 minutes) and 99.6% (FIG. 5B, tₕ=5 minutes). If we heat the material to 400 degree Celsius within 3 minutes, the current applied when heating is approximately 300 Ampere. The current is approximately 200 Ampere when the duration of heating is to 5 minutes. With a smaller current, and hence slower heating rate (e.g., corresponding to tₕ=5) there is a small decrease of relative density (compared to a larger current corresponding to higher heating rate, such as corresponding to tₕ=3). Furthermore, it is noticed that a smaller current leads to less decomposition of the Zn₄Sb₃ phase.

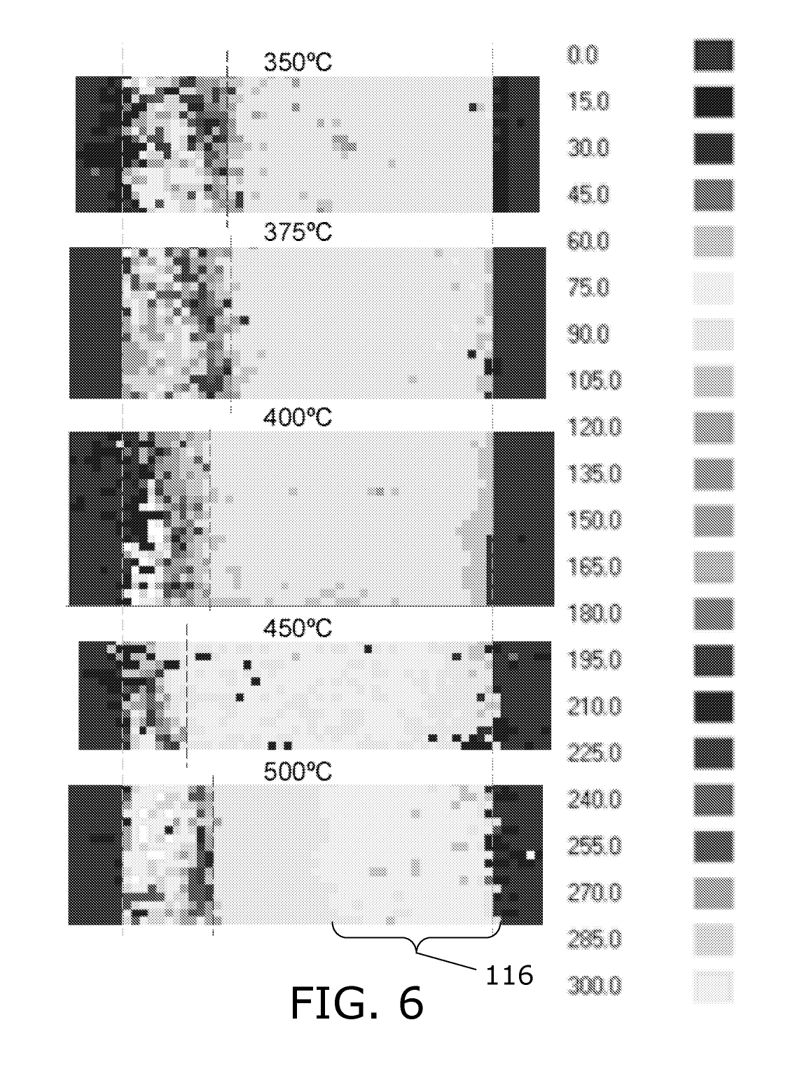

FIG. 6 shows the effect of sintering temperature T on the decomposition of Zn₄Sb₃. In FIG. 6, six Seebeck microprobe scans can be seen, corresponding to (from top to bottom), samples which have been sintered at a sintering temperature of 350, 375, 400, 450 and 500 degree Celsius. Surprisingly, decreased sintering temperatures do not lead to less decomposition of the material. Compared to the sample sintered at 400 degree Celsius, the pellets sintered at 350 and 375 degree Celsius suffer more severe decomposition. When sintered at 450 degree Celsius, the width of the ZnSb phase does not grow compared to both the pellet sintered at 400 degree Celsius and the pellet sintered at 500 degree Celsius. However, the matrix (i.e., the portion of the pellet which is between the middle and the rightmost dotted lines, and which is the largest portion) of the pellet seems to be dominated by another phase with lower Seebeck coefficient. It might be a mixture of zinc poor sub-phase of Zn₄Sb₃ and Zn. When sintered at 500 degree Celsius, the mixture is accumulated to the right. The relative densities of the five samples (degree Celsius in parenthesis) are 95% (350), 100% (375), 99.9% (400), 100% (450) and 100% (500), respectively.

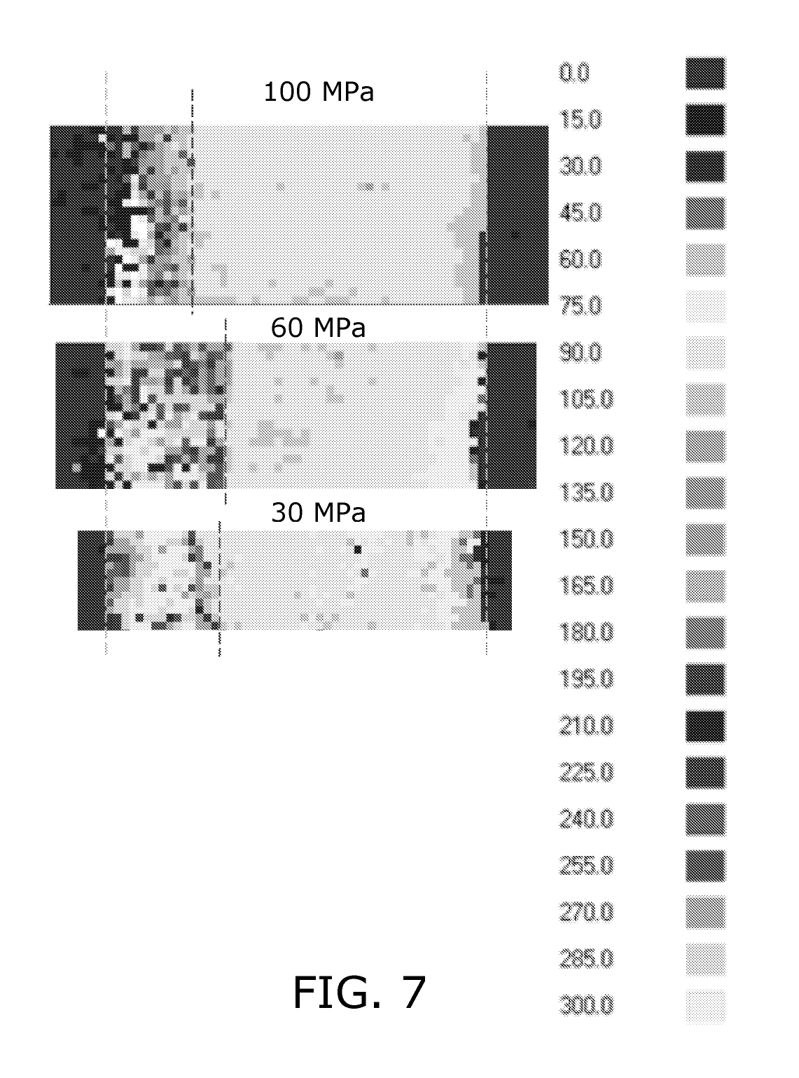

FIG. 7 shows the effect of applied pressure on the degradation of Zn₄Sb₃. From top to bottom, the pellets in FIG. 7 have been produced with an applied pressure of 100 MPa, 60 MPa, and 30 MPa. The pellets produced with pressures of 60 MPa and 30 MPa decompose more to a larger extent compared with the pellet pressed with a pressure of 100 MPa. Larger areas of ZnSb phases are generated at the left sides. The areas with lower Seebeck coefficients on the right sides also seem to grow with lower pressure. Moreover, the pellet sintered with 30 MPa breaks easily after taking it out of the die, indicating a worse mechanical stability.

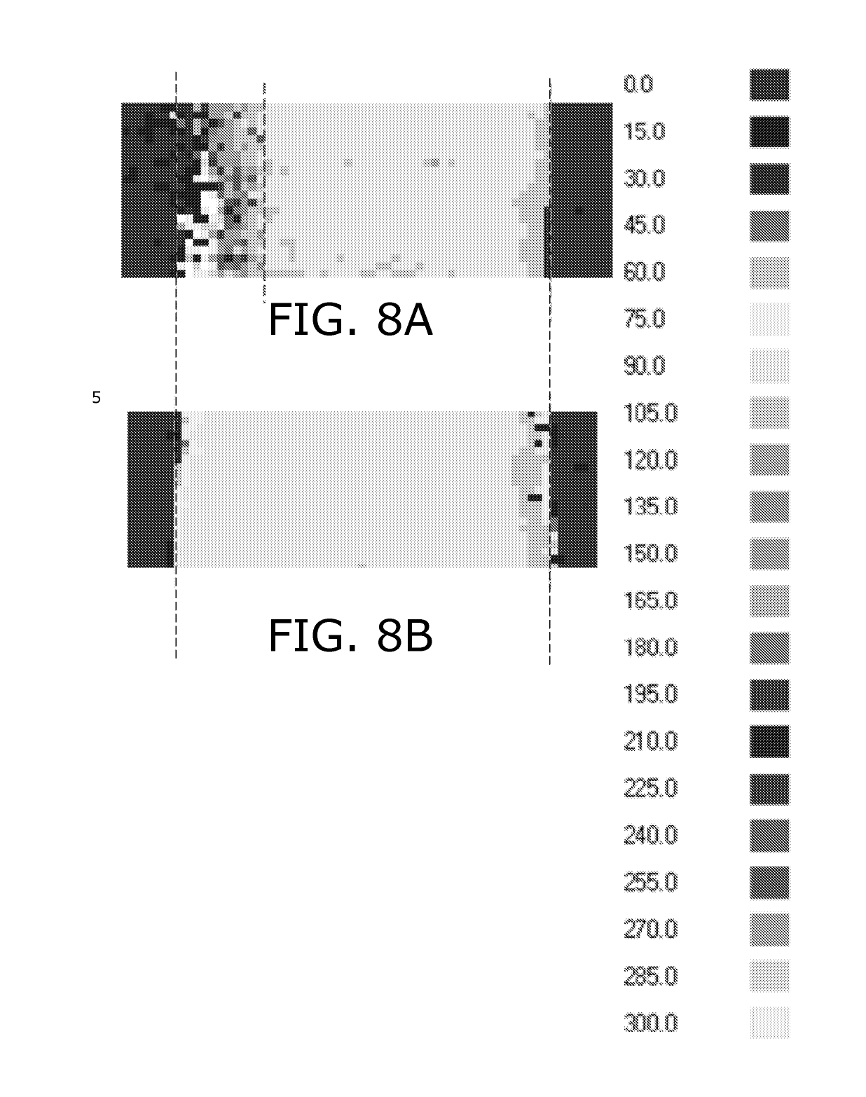

FIG. 8 shows the Seebeck microprobe patterns of two Zn₄Sb₃ pellets pressed, respectively, with a Zn foil placed adjacent to the powder mixture at the side where the current comes into the pellets during applying current and pressure (FIG. 8B), and without such Zn foil (FIG. 8A). The Zn foil in the present embodiment is about 0.2 mm thick, and the zinc in the zinc foil is used to compensate the Zn lost in the pellet during sintering due to electromigration. No ZnSb phase is observed in the pellet pressed with Zn foil. Instead, only a thin layer can be seen which has Seebeck coefficients of approximately 75 microV/K, which region is likely to be a mixture of Zn₄Sb₃ and Zn.

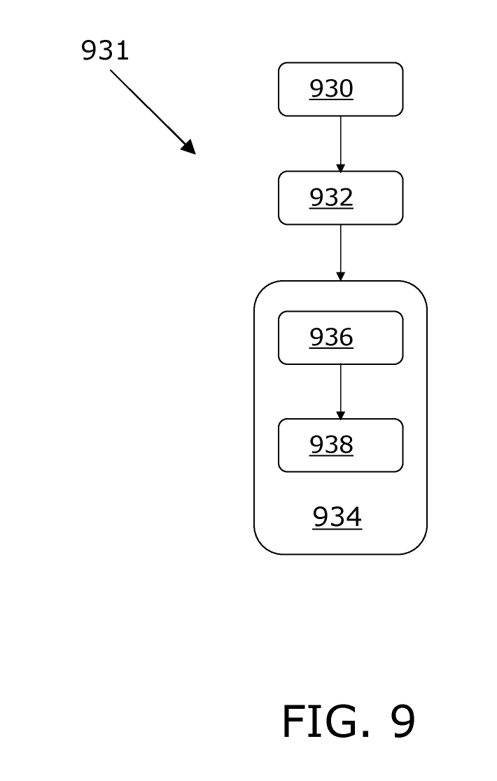

FIG. 9 is a flow-chart of a method according to the invention, which shows a method 931 for producing a solid element comprising Zn4Sb3, the method comprising
mixing 930 powders of elemental zinc and elemental antimony so as to obtain a mixed powder comprising elemental zinc and elemental antimony,
placing 932 the mixed powder in a container, and
performing 934 a combined synthesis and sintering process comprising
   applying 936 a pulsed current through the mixed powder, so as to increase the temperature of the mixed powder to an interval within 200-1000 degree Celsius, and
   applying 938 a pressure of at least 1 Mega Pascal to the mixed powder, and
      wherein the steps of applying the pulsed current through the mixed powder and applying the pressure to the mixed powder occur simultaneously.

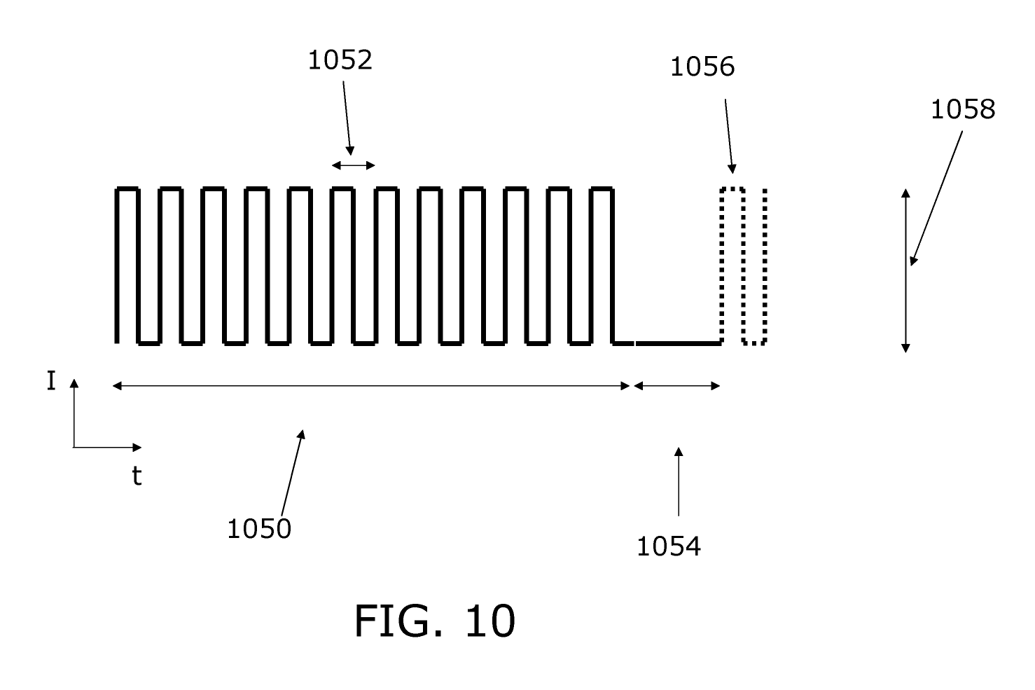

FIG. 10 shows an exemplary pulsed current which is depicted as a curve with current I on the vertical axis and time t on the horizontal axis. The figure shows a train of pulses, such as 12 pulses, span a period 1050 which may be 39.6 milliseconds. It is contemplated, that the number of pulses may be larger or smaller, and that the period 1052 of the individual pulses—which is 3.3 milliseconds here—may be larger or smaller. The pulses are shown to be equidistantly placed square pulses of equal height. However, they may not necessarily be equidistantly placed, and may take other forms, such as Gaussian, sinusoidal, triangular or other shape, and they may have different heights. The train of pulses is followed by a period 1054 with zero current, which period is 6.6 milliseconds, but it is contemplated that this period may be longer or shorter. Thereafter a new cycle 1056 is initiated. In the present example, the pulses have a peak current value 1058 of 200 Ampere, but this could also be other values, such as 300 Ampere.

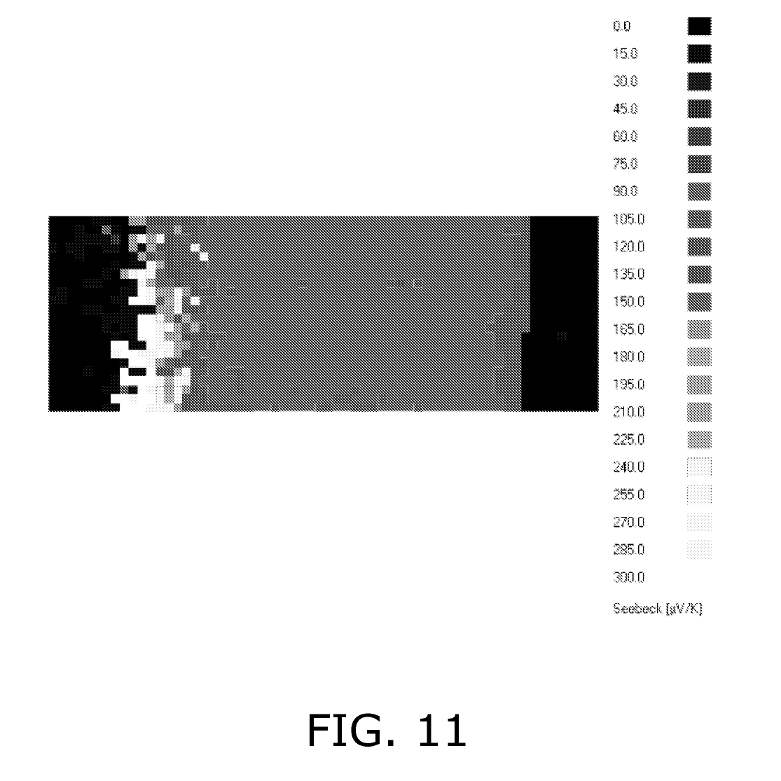

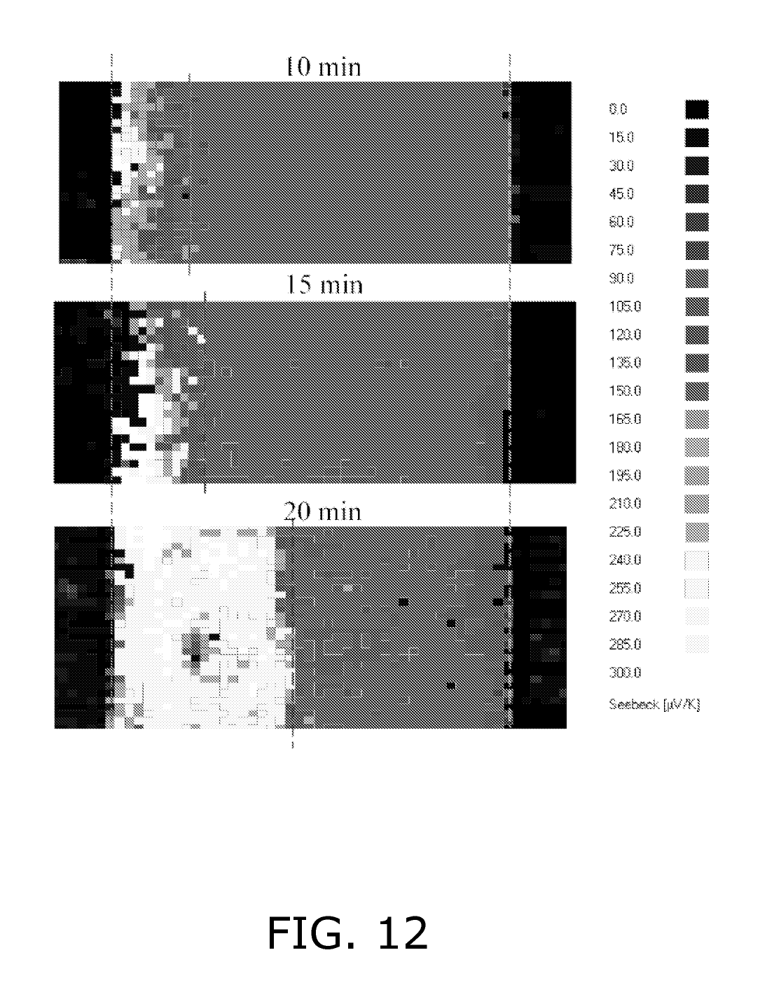

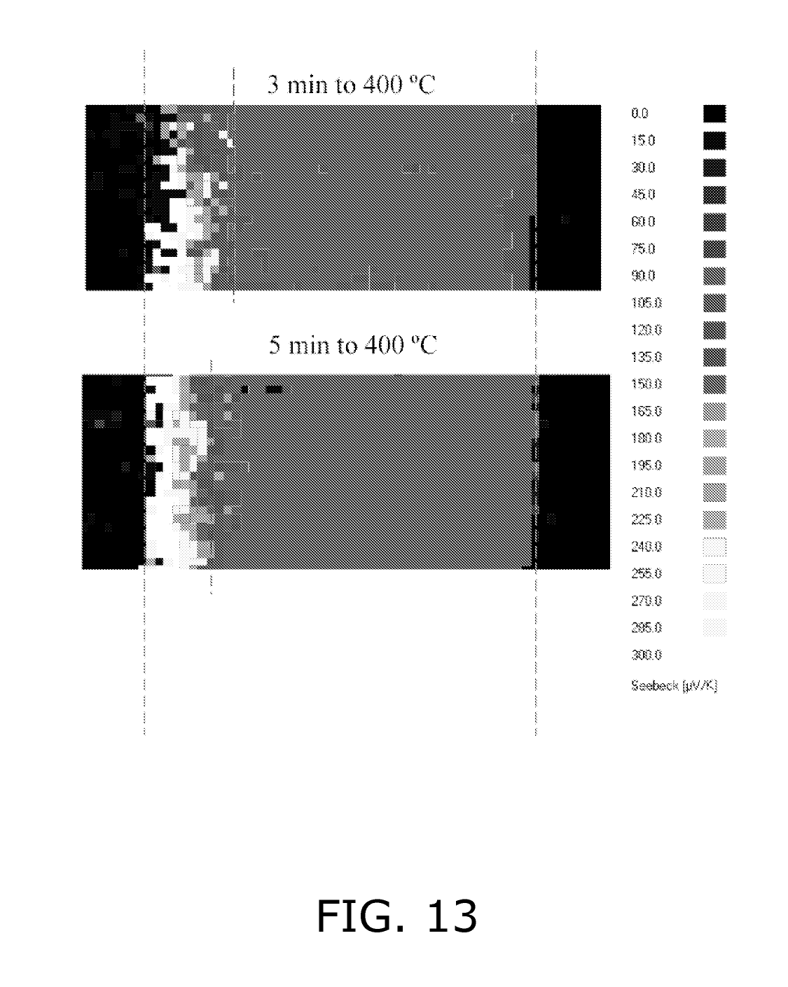

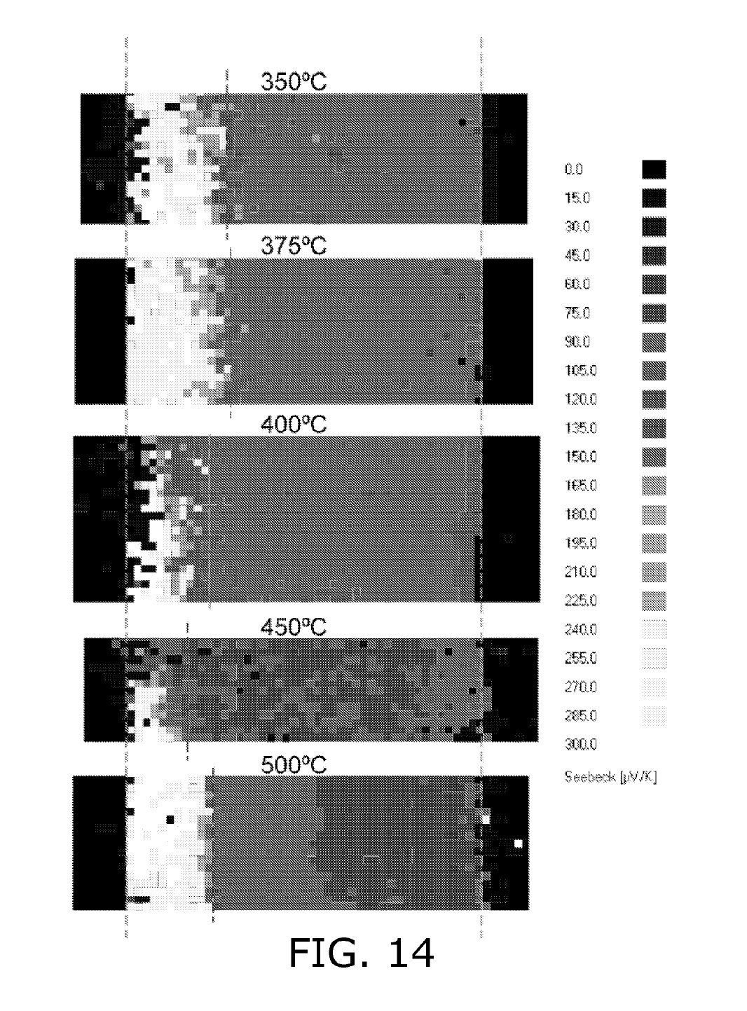

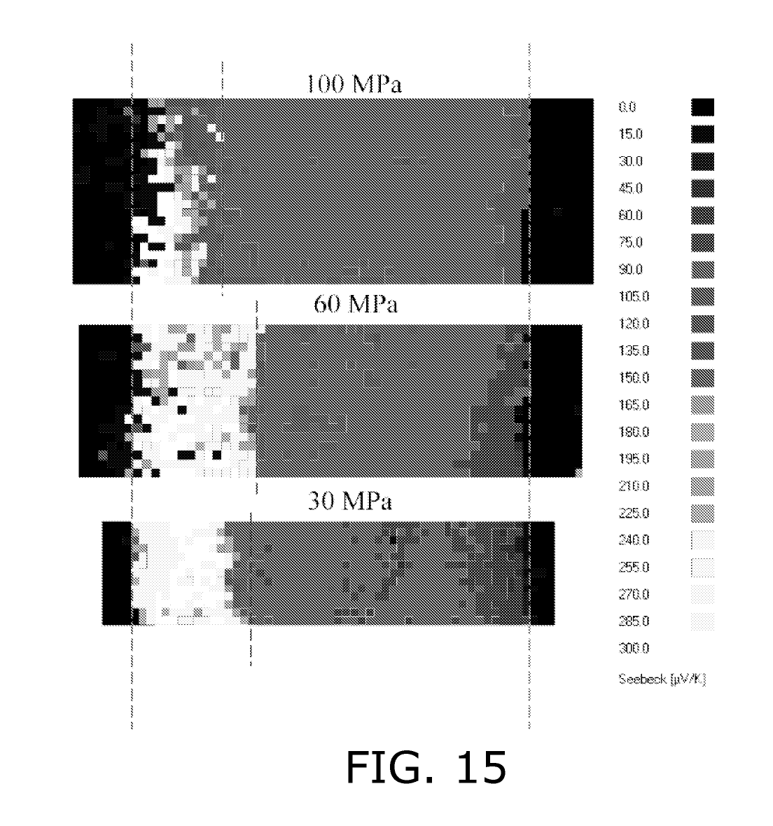

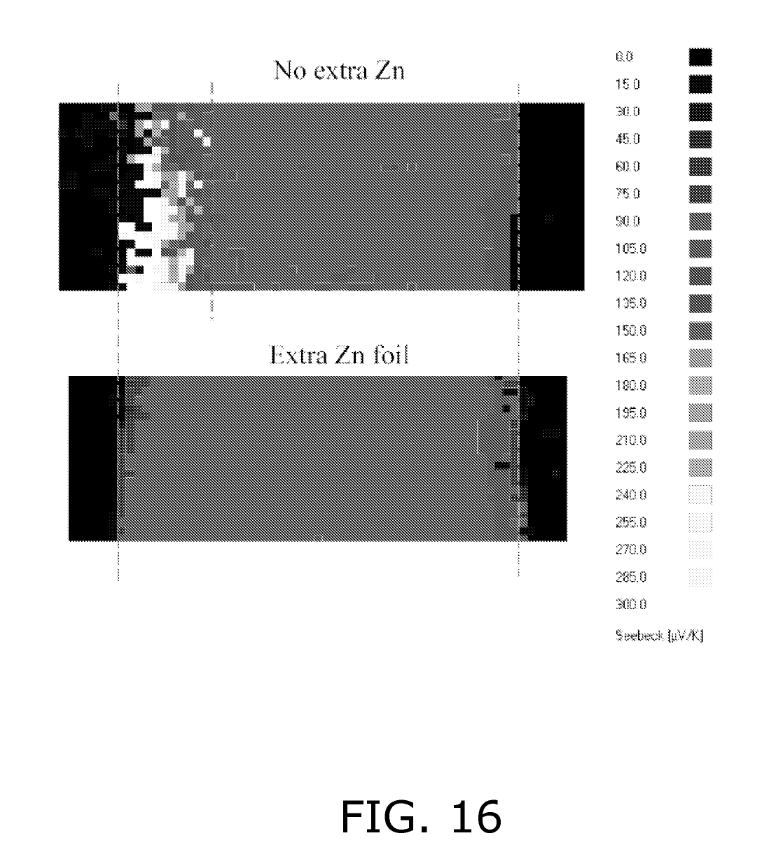

FIGS. 11-16 show, respectively FIGS. 2, 4-8 with another colour scale, i.e., the pairs of FIGS which correspond are FIG. 2/11, FIG. 4/12, FIG. 5/13, FIG. 6/14, FIG. 7/15, FIG. 8/16.

To sum up, the present invention relates to a method for producing a solid element, which comprises the thermoelectrically active material beta-Zn4Sb3. The method utilizes that is possible to directly synthesize and press pellets of Zn4Sb3 starting from powders of Zn and Sb, by mixing powders of Zn and Sb so as to obtain a mixed powder comprising elemental zinc and elemental antimony, placing the mixed powder in a container and simultaneously applying a pulsed current, such as to heat up the powders, and applying a pressure such as to compact the powder mix. The gist of the invention might be seen as exploiting the basic insight, that the cumbersome and time- and energy consuming steps of synthesis and pressing of Zn and Sb, so as to achieve a solid element comprising Zn₄Sb₃, can be combined into a single step where the synthesis and pressing is effected simultaneously.

Although the present invention has been described in connection with the specified embodiments, it should not be construed as being in any way limited to the presented examples. The scope of the present invention is set out by the accompanying claim set. In the context of the claims, the terms “comprising” or “comprises” do not exclude other possible elements or steps. Also, the mentioning of references such as “a” or “an” etc. should not be construed as excluding a plurality. The use of reference signs in the claims with respect to elements indicated in the figures shall also not be construed as limiting the scope of the invention. Furthermore, individual features mentioned in different claims, may possibly be advantageously combined, and the mentioning of these features in different claims does not exclude that a combination of features is not possible and advantageous.

1. A method for producing a solid element comprising at least 90 wt % Zn4Sb3, the method comprising:
mixing powders of elemental zinc and elemental antimony so as to obtain a mixed powder comprising elemental zinc and elemental antimony,
placing the mixed powder in a container, and
performing a combined synthesis and sintering process comprising:
applying a pulsed current through the mixed powder, so as to increase the temperature of the mixed powder to an interval within 200-1000 degree Celsius, and
applying a pressure of at least 1 Mega Pascal to the mixed powder,
wherein the steps of applying the pulsed current through the mixed powder and applying the pressure to the mixed powder occur simultaneously.

2-15. (canceled)

16. The method according to claim 1, wherein the method comprises a one-step direct synthesis and pressing process for producing Zn4Sb3 using SPS, wherein synthesis of Zn4Sb3 from powders of elemental zinc and elemental antimony is carried out simultaneously with the pressing of the mixed powder into a pellet.

17. The method according to claim 1, wherein the step of mixing powders of elemental zinc and elemental antimony is carried out so as to obtain a mixed powder comprising at least 50 wt % elemental zinc and elemental antimony.

18. The method according to claim 1, wherein a period of time from having the powders of elemental Zn and elemental Sb until a solid element of Zn4Sb3 is provided is within less than 24 hours.

19. The method according to claim 1, wherein a period of time from having the powders of elemental Zn and elemental Sb until a solid element of Zn4Sb3 is provided is within 4 hours.

20. The method according to claim 1, wherein a period of time from having the powders of elemental Zn and elemental Sb until a solid element of Zn4Sb3 is provided is within 60 minutes.

21. The method according to claim 1, wherein the step of applying a pulsed current through the mixed powder, is carried out so as to increase the temperature of the mixed powder to an interval within 350-500 degree Celsius.

22. The method according to claim 1, wherein the pulsed current is a current, which repeatedly increases and decreases with respect to time.

23. The method according to claim 1, wherein the method further comprises:
placing an element comprising zinc adjacent to the mixed powder to allow zinc ions to electromigrate from the element to the mixed powder during the step of applying the pulsed current through the mixed powder.

24. The method according to claim 1, wherein the pressure that is applied to the mixed powder is at least 60 Mega Pascal.

25. The method according to claim 1, wherein the applied current through the mixed powder is sufficient to heat the sample to at least 350 degree Celsius.

26. The method according to claim 1, wherein the applied current is substantially turned off within less than 24 hours.

27. The method according to claim 1, wherein the applied pressure is released within less than 24 hours.

28. The method according to claim 1, wherein the heating rate is at least 50 degrees Celsius per minute.

29. The method according to claim 1, wherein the heating rate is at most 50 degree Celsius per minute.
